(19) United States
(12) Patent Application Publication
(10) Pub. No.: US 2020/0090996 A1
(43) Pub. Date: Mar. 19, 2020

(54) METHOD OF FORMING A CONTACT PLUG OF A SEMICONDUCTOR INTEGRATED CIRCUIT DEVICE

(71) Applicant: SK hynix Inc., Icheon-si Gyeonggi-do (KR)

(72) Inventors: Hyun Jun YOO, Seoul (KR); Tae Hwan KIM, Yongin-si Gyeonggi-do (KR)

(73) Assignee: SK hynix Inc., Icheon-si Gyeonggi-do (KR)

(21) Appl. No.: 16/216,845

(22) Filed: Dec. 11, 2018

(30) Foreign Application Priority Data
Sep. 18, 2018 (KR) 10-2018-0111429

(51) Int. Cl. H01L 21/768; H01L 21/02; H01L 27/105

(52) U.S. Cl. CPC H01L 21/76897; H01L 21/76871; H01L 27/1052; H01L 21/02532; H01L 21/02211; H01L 21/02063

(57) ABSTRACT

In a method of forming a contact plug of a semiconductor integrated circuit device, an insulating interlayer may be formed on a semiconductor substrate with a conductive region including silicon. The insulating interlayer may be etched until the conductive region may be exposed to form a contact hole in the insulating interlayer. Surfaces of the contact hole and the conductive region may be dry cleaned. First and second precursors may be used to form a seed layer on the surfaces of the contact hole and the conductive region, the first precursor configured to supply a silicon source and the second precursor configured to suppress a growth of the silicon.

The present application claims priority under 35 U.S.C. § 119(a) to Korean application number 10-2018-0111429, filed on Sep. 18, 2018, in the Korean Intellectual Property Office, which is incorporated herein by reference in its entirety.

### BACKGROUND

### 1. Technical Field

Various embodiments generally relate to a method of fabricating a semiconductor integrated circuit device, and more particularly, to a method of forming a contact plug of a semiconductor integrated circuit device.

### 2. Related Art

A semiconductor integrated circuit device may be highly integrated, and, thus, a contact plug having a high aspect ratio may be required. In order to form the contact plug having the high aspect ratio, it may be required to form a deep contact hole using an over-etching process.

When a junction region is opened by the over-etching process, a surface of a semiconductor substrate including silicon may be damaged or a native oxide layer may be generated on the surface of the semiconductor substrate in the junction region. Because the native oxide layer hinders the generation of a polysilicon layer in the contact plug, it may be required to remove the native oxide layer by a cleaning process before forming the contact plug.

However, when the native oxide layer is removed by the cleaning process, an insulating interlayer, which defines the deep contact hole and includes a material substantially the same as that of the native oxide layer, and insulating layers on the junction region may be damaged. Further, when the semiconductor substrate is transferred to a chamber for forming the polysilicon layer after performing the cleaning process, a secondary native oxide layer may be formed on the junction region. Thus, it may be difficult to form the polysilicon layer having a uniform thickness.

Furthermore, when the contact hole having the high aspect ratio is filled with the polysilicon layer, a void and a seam may be generated in the contact plug due to a structural characteristic of the contact hole. The void and the seam in the contact plug may cause deteriorations of electrical characteristics in an interconnection layer.

### SUMMARY

In an embodiment of the present disclosure, in a method of forming a contact plug of a semiconductor integrated circuit device, an insulating interlayer may be formed on a semiconductor substrate with a conductive region including silicon. The insulating interlayer may be etched until the conductive region may be exposed to form a contact hole in the insulating interlayer. The semiconductor substrate may be loaded into a process chamber. An etching gas may be supplied to the process chamber to dry dean surfaces of the contact hole and the conductive region. A silicon source and a source for suppressing a generation of the silicon may be supplied to the process chamber, at time periods that at least partially overlap each other, to form a seed layer on the surfaces of the contact hole and the conductive region. A silicon source may be supplied to the process chamber to grow a polysilicon layer, which may have a thickness for filling the contact hole, from the seed layer.

In an embodiment of the present disclosure, in a method of forming a contact plug of a semiconductor integrated circuit device, an insulating interlayer may be formed on a semiconductor substrate with a conductive region including silicon. The insulating interlayer may be etched until the conductive region may be exposed to form a contact hole in the insulating interlayer. Surfaces of the contact hole and the conductive region may be dry cleaned. First and second precursors may be used to form a seed layer on the surfaces of the contact hole and the conductive region, the first precursor configured to supply a silicon source and the second precursor configured to suppress a growth of the silicon.

### BRIEF DESCRIPTION OF THE DRAWINGS

The above and other aspects, features and advantages of the subject matter of the present disclosure will be more clearly understood from the following detailed description taken in conjunction with the accompanying drawings, in which:

FIG. 1 is a cross-sectional view diagram illustrating an apparatus for fabricating a semiconductor device in accordance with examples of embodiments;

FIGS. 2 to 7 are cross-sectional views illustrating a method of forming a contact plug in accordance with examples of embodiments; and

FIGS. 8 to 20 are cross-sectional views illustrating a method of forming a polysilicon contact plug of a semiconductor memory device in accordance with examples of embodiments.

### DETAILED DESCRIPTION

Various embodiments will be described in with reference to the accompanying drawings. The drawings are schematic illustrations of various embodiments (and intermediate structures). As such, variations from the configurations and shapes of the illustrations as a result, for example, of manufacturing techniques and/or tolerances, are to be expected. Thus, the described embodiments should not be construed as being limited to the particular configurations and shapes illustrated herein but may include deviations in configurations and shapes which do not depart from the spirit and scope of the disclosure as defined in the appended claims.

Although a few embodiments of the present invention will be shown and described, it will be appreciated by those of ordinary skill in the art that changes may be made in these embodiments without departing from the principles and spirit of the disclosure.

Same reference numerals refer to same elements throughout the specification. Thus, even though a reference numeral is not mentioned or described with reference to a drawing, the reference numeral may be mentioned or described with reference to another drawing. In addition, even though a reference numeral is not shown in a drawing, it may be mentioned or described with reference to another drawing.

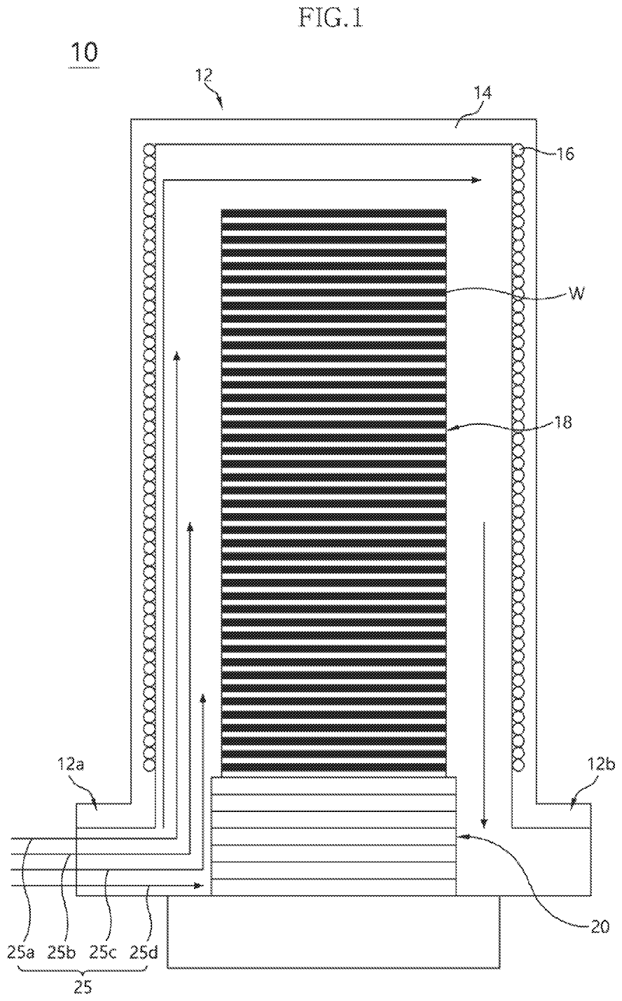

FIG. 1 is a cross-sectional view diagram illustrating an apparatus for fabricating a semiconductor device in accordance with examples of embodiments.

Referring to FIG. 1, the semiconductor fabrication apparatus 10 may be a vertical type apparatus. The semiconductor fabrication apparatus 10 may receive a plurality of semiconductor substrates W to successively perform a cleaning process and a deposition process. The semiconductor fabrication apparatus 10 may include a cylindrical vertical furnace 12. An inlet 12a may be arranged at a lower portion of a sidewall of the furnace 12. An outlet 12b opposite to the inlet 12a may be arranged at the sidewall of the furnace 12. The furnace 12 may have an opened bottom surface. The sidewall and an upper surface of the furnace 12 may be covered by an adiabatic layer 14. A heater 16 for heating the semiconductor substrate W may be positioned on an inner surface of the adiabatic layer 14. A boat 18 with the semiconductor substrates W may be loaded into the furnace 12 through the opened bottom surface. The semiconductor substrates W may be placed on a pedestal 20.

A gas pipe 25 may be inserted into the inlet 12a of the furnace 12. The gas pipe 25 may include a plurality of pipes 25a˜25d. The pipes 25a˜25d may have different heights. Thus, a cleaning gas, a pre-processing source, a first precursor, a second precursor and/or a third precursor may be uniformly supplied to the vertically stacked semiconductor substrates W. In examples of embodiments, the gas pipe for supplying the cleaning gas may include a plurality of pipes having different heights. The gas pipe for supplying the pre-processing source may include a plurality of pipes having different heights. The gas pipe for supplying the first precursor may include a plurality of pipes having different heights. The gas pipe for supplying the second precursor may include a plurality of pipes having different heights. The gas pipe for supplying the third precursor may include a plurality of pipes having different heights.

The cleaning gas may include a hydrogen bromide (HBr) gas. The pre-processing source may include diisopropylaminosilane (DIPAS). The first precursor may include a silicon source without Cl (chlorine) such as monosilane. The second precursor may include a source for suppressing a generation of silicon such as dichlorosilane (DCS). The third precursor may include disilane containing a plurality of silicon couplers for promoting the growth of the silicon. Additionally, various gases such as a doping gas, a purge gas, etc., as well as the cleaning gas, the pre-processing source, the first precursor, the second precursor and/or the third precursor may be supplied to the furnace 12.

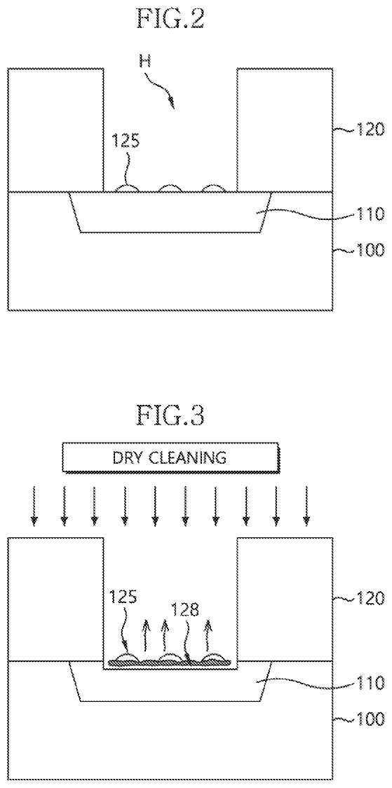

FIGS. 2 to 7 are cross-sectional views illustrating a method of forming a contact plug in accordance with examples of embodiments.

Referring to FIG. 2, a conductive region 110 may be formed in a semiconductor substrate 100. For example, conductive impurities may be implanted into the semiconductor substrate 100 to form the conductive region 110. Alternatively, a conductive layer including silicon may be formed in the semiconductor substrate 100 to form the conductive region 110.

An insulating layer 120 may be formed on the semiconductor substrate 100 with the conductive region 110. For example, the insulating layer 120 may include silicon oxide.

A predetermined portion of the insulating layer 120 may be etched until the conductive region 110 may be exposed to form a contact hole H in the insulating layer 120. For example, the contact hole H may have a high aspect ratio having a short diameter and a deep depth. In order to form the contact hole H having the high aspect ratio, the insulating layer 120 may be over-etched.

Referring to FIG. 3, etched residues may remain on a surface of the conductive region 110 by the over-etching process for forming the contact hole H. Alternatively, the surface of the conductive region 110 may be damaged by the over-etching process for forming the contact hole H. In order to remove the etched residues or the damaged region, a wet cleaning process or a dry cleaning process may be additionally performed.

The semiconductor substrate 100 on which the process for forming the contact hole and the cleaning process may be performed may be received in the boat 18. The boat 18 may be loaded into the furnace 12 of the semiconductor fabrication equipment 10. As mentioned above, although the cleaning process may be performed on the semiconductor substrate 100, an undesired native oxide layer 125 may be formed on the surface of the conductive region 110 when the semiconductor substrate 100 is transferred to the furnace 12.

In examples of embodiments, in order to remove and restore the damaged region, a cleaning gas including an HBr gas may be supplied into the furnace 12. The HBr gas may function to etch the silicon. When the HBr gas is supplied into the furnace 12, the HBr gas may react with the conductive region 110 exposed by the native oxide layer 125. Byproducts 128 (for example, Si+HBr=SixHyBrz ⬆) generated by the reaction between the HBr gas and the conductive region 110 may be removed by a purge gas. The byproducts may be detached from the conductive region 110 by the purge gas so that the native oxide layer 126 on the byproducts 128 may be simultaneously lifted off. Because the HBr gas has an etching selectivity with respect to the silicon oxide layer, only the native oxide layer 126 may be removed without damages of the insulating layer 120. The HBr gas may have an amount for partially decreasing a thickness of the conductive region. For example, the amount of the HBr gas may be about 400 sccm (standard cubic centimeter per minute) to about 2,000 sccm.

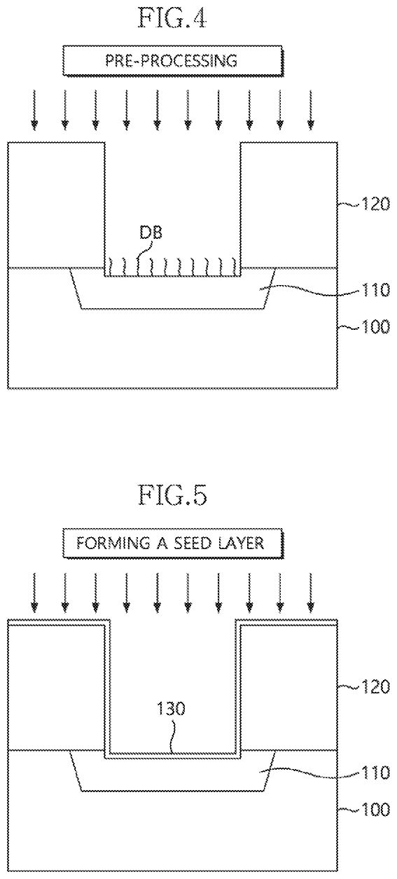

Referring to FIG. 4, after cutting off the supply of the HBr gas, a pre-processing source may be supplied into the furnace 12. The pre-processing source may include a liquid silicon source such as diisopropylaminosilane (DIPAS). The pre-processing source may remove dangling bonds DB on the surfaces of the conductive region 110 and the contact hole H to improve a seed incidence rate. An amount of the DIPAS source may be about 150 sccm to about 250 sccm.

Referring to FIG. 5, a first precursor and a second precursor may be supplied into the furnace 12 to form a seed layer 130. In some embodiments, the first and second precursors may be supplied at time periods which simultaneously overlap each other or substantially simultaneously overlap each other to form the seed layer 130. In other embodiments the first and second precursors may be supplied at time periods that partially overlap each other to form the seed layer 130. In some embodiments, the first and second precursors may be supplied within substantially the same time period or the same time period. In examples of embodiments, the first precursor may function to grow a seed. The second precursor may function to suppress the growth of the seed. The first precursor may include a silicon source without CI, for example, monosilane (SiH₄). The second precursor may include a silicon source with CI, for example, dichlorosilane (SiH₂Cl₂) (DCS). The first precursor may be thermally decomposed to form a silicon seed on the surface of the conductive region 110. The silicon in the second precursor may be adsorbed on the surface of the conductive region 110 to suppress the silicon growth. The suppressing of the silicon growth may provide the silicon seed with a small size to increase a density of the silicon seed. An amount ratio between the first precursor and the second precursor may be about 3˜7:1 in the process for forming the seed layer 130. For example, the monosilane as the first precursor having an amount of about 400 sccm to about 600 sccm and the DCS as the second precursor having an amount of about 60 sccm to about 200 sccm may be supplied to the furnace 12 for about 30 minutes to about 60 minutes to form the seed layer 130.

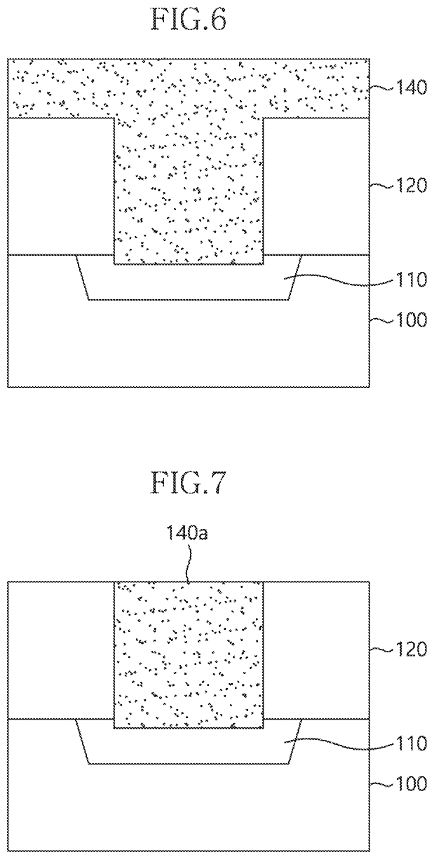

Referring to FIG. 6, a silicon source may be supplied into the furnace 12 to epitaxial grow a polysilicon layer 140 in the contact hole H from the seed layer 130. The silicon source may include the monosilane used as the first precursor. Alternatively, the silicon source may include a source having a multiple silicon coupler such as disilane. A doping gas such as a Phosphane (PH₃) gas may be supplied into the furnace 12 simultaneously with the silicon source to provide the polysilicon layer 140 with conductivity. In order to improve roughness of the polysilicon layer 140, the DCS used as the second precursor may be additionally supplied into the furnace 12 together with the silicon source.

When the second precursor such as the DCS is supplied during the process for forming the seed layer 130 to increase the density of the seed layer 130, the second precursor such as the DCS may be supplied during the epitaxial growth process to delay the rapid growth of the silicon. Thus, because the growth of the polysilicon layer 140 may be slowly progressed, the roughness of the surface of the polysilicon layer 140 may be decreased to reduce voids and seams. Further, the amount ratio between the first precursor and the second precursor may be about 3˜7:1 in the polysilicon epitaxial growth process considered a growth rate of the polysilicon layer 140. For example, the first precursor having an amount of about 400 sccm to about 600 sccm and the second precursor having an amount of about 60 sccm to about 200 sccm may be supplied to grow the polysilicon layer 140.

Referring to FIG. 7, the polysilicon layer 140 may be etched-back until the surface of the insulating layer 120 may be exposed to form a contact plug 140a.

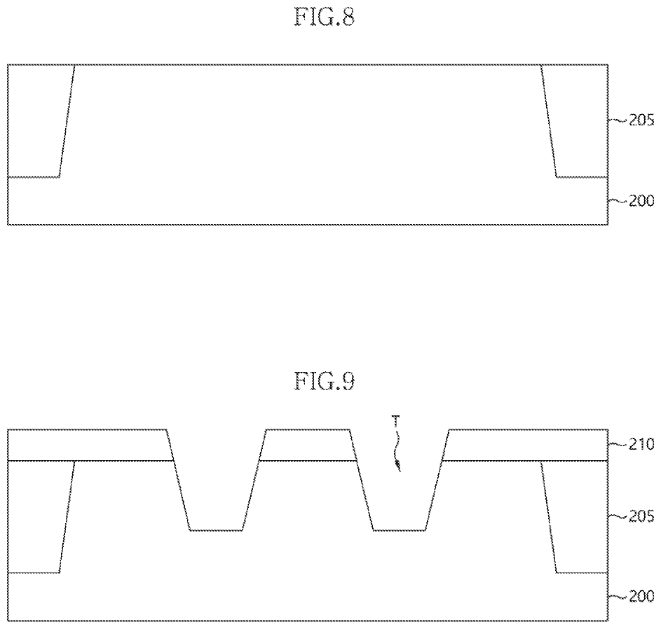

FIGS. 8 to 20 are cross-sectional views illustrating a method of forming a polysilicon contact plug of a semiconductor memory device in accordance with examples of embodiments.

Referring to FIG. 8, an isolation layer 205 may be formed in a semiconductor substrate 200 to define an active region.

Referring to FIG. 9, a hard mask layer 210 for defining a gate region may be formed on the semiconductor substrate 200. The semiconductor substrate 200 exposed by the hard mask layer 210 may be etched to form a trench T.

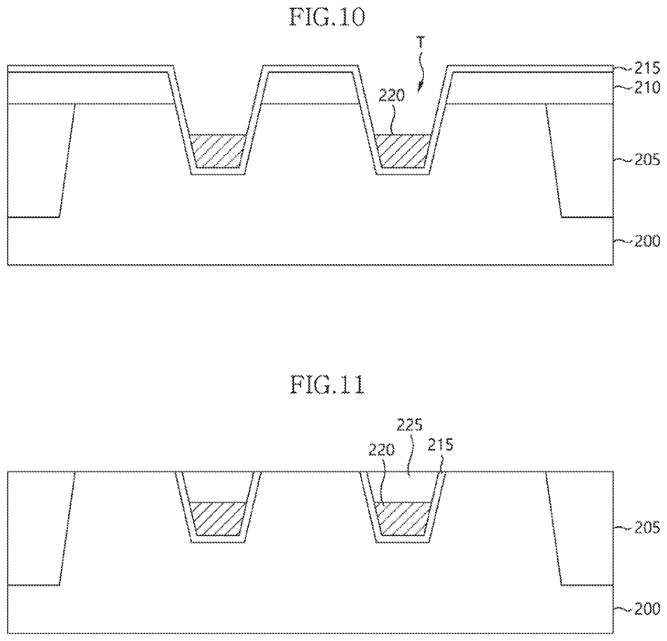

Referring to FIG. 10, a gate insulating layer 215 may be formed on surfaces of the trench T and the hard mask layer 210. A conductive layer may be formed on the gate insulating layer 215 to fill up the trench T with the conductive layer. The conductive layer may be etched-back to form a buried gate 220 in a lower region of the trench T. Alternatively, gates having various structures as well as the buried gate 220 may be formed in the trench T.

Referring to FIG. 11, a gap-filling insulating layer 225 may be formed on the gate 220 and the gate insulating layer 215. The gap-filling insulating layer 225 may be etched-back to remain the gap-filling insulating layer 225 in the trench T.

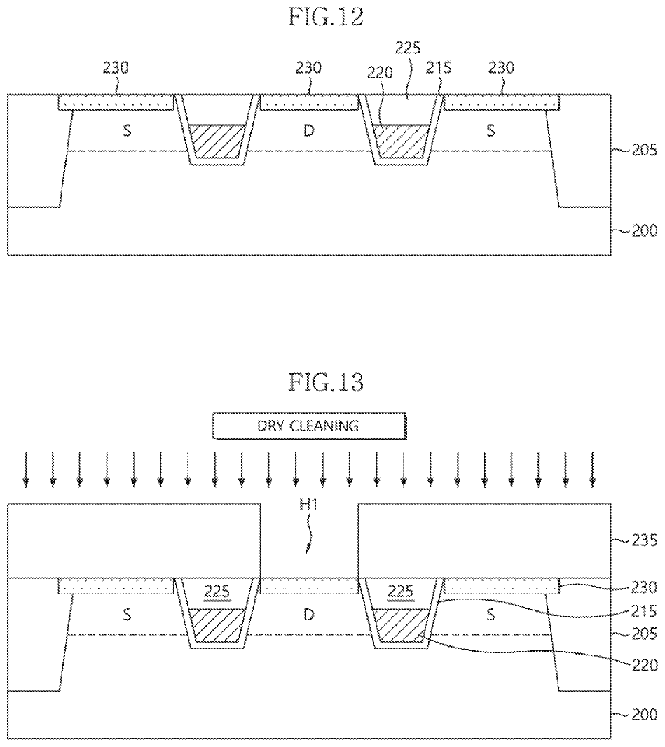

Referring to FIG. 12, impurities may be implanted into the active regions at both sides of the gate 220 to form a source S and a drain D. An interface of the source S and the drain D may be lower than an upper surface of the gate 220 and higher than a lower surface of the gate 220. In order to decrease contact resistances of the source S and the drain D, a contact pad region 230 may be additionally formed in upper regions of the source S and the drain D. Upper surfaces of the source S and the drain D and the upper surface of the isolation layer 205 adjacent to the upper surfaces of the source S and the drain D may be etched to form a recess. The recess may be filled with a silicon layer or a polysilicon layer having high concentration impurities to form a contact pad 230. Alternatively, the high concentration impurities may be implanted into the source S and the drain D to form the contact pad region 230. In examples of embodiments, a portion of the contact pad region 230 on the source may correspond to a part of the source S. A portion of the contact pad region 230 on the drain D may correspond to a part of the drain D.

Referring to FIG. 13, a first insulating interlayer 235 may be formed on the isolation layer 205, the gap-filling insulating layer 225, the gate insulating layer 215 and the contact pad region 230. The first insulating interlayer 235 may be etched until the contact pad region on the drain D may be exposed to form a first contact hole H1. Additionally, in order to ensure a contact margin, the gap-filling insulating layer 225 adjacent to the contact pad region 230 on the drain D may be partially exposed during the formation of the first contact hole H1. The first contact hole H1 may correspond to a bit line contact hole.

The semiconductor substrate 200 with the first contact hole H1 may be loaded into a process chamber. The process chamber may include a batch type vertical furnace configured to receive a plurality of the semiconductor substrates 200. An HBr gas may be supplied into the process chamber to dry clean the surface of the contact pad region 230 exposed through the first contact hole H1, the surface of the first insulating interlayer 235 and the surface of the first contact hole H1. The HBr gas may be reacted with silicon in the contact pad region 230 to partially etch the upper surface of the contact pad region 230. A native oxide layer on the contact pad region 230 may be lifted off together with the upper surface of the contact pad region 230 by the dry cleaning process using the HBr gas. Further, because the HBr gas might not react with an insulating material, the first insulating interlayer 235 and the gap-filling insulating layer 225 may be damaged by the HBr gas.

Additionally, a wet cleaning process or a dry cleaning process may be performed between the process for forming the first contact hole H1 and the process for loading the semiconductor substrate 200 into the process chamber.

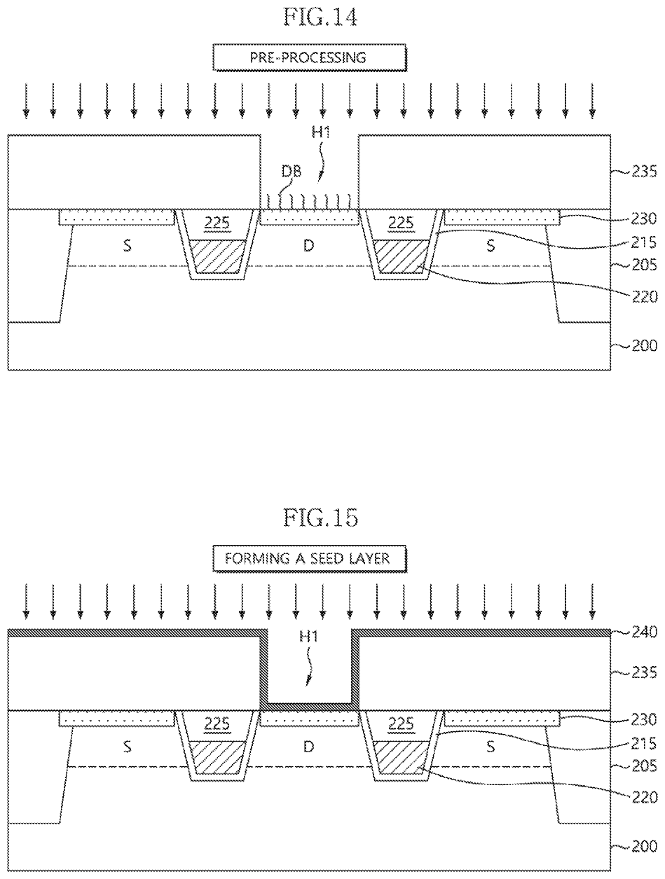

Referring to FIG. 14, a liquid source such as DIPAS may be supplied into the process chamber without cutoff of vacuum to pre-process the exposed contact pad region 230, the surface of the first insulating interlayer 235 and the surface of the first contact hole H1. The pre-process may remove dangling bonds DB on the exposed contact pad region 230, the surface of the first insulating interlayer 235 and the surface of the first contact hole H1 by the chemical reaction to form an environment where the seed such as silicon atoms may be readily adsorbed.

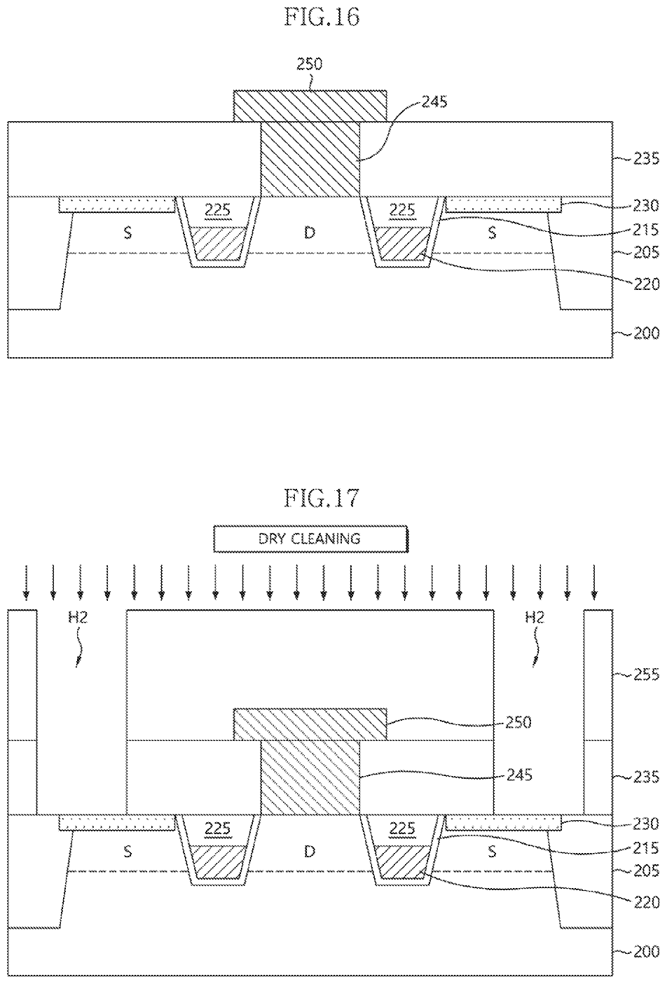

Referring to FIG. 15, a silicon source without chlorine (Cl) as a first precursor such as monosilane and a silicon source with Cl as a second precursor such as DCS may be supplied into the process chamber without the cutoff of the vacuum to form a silicon seed layer 240 on the exposed contact pad region 230, the upper surface of the first insulating interlayer 235 and the inner surface of the first contact hole H1. In examples of embodiments, the first precursor may function as to grow a seed on the exposed surface of the contact pad 230, the upper surface of the first insulating interlayer 235 and the inner surface of the first contact hole H1. The second precursor may function to suppress the growth of the seed. The seed layer 240 may be formed using the first and second precursors to provide the seed layer 240 on the surface of the contact pad region 230, the surface of the first insulating interlayer 235 and the inner surface of the first contact hole H1 with a high density.

Referring to FIG. 16, a silicon source may be supplied into the process chamber to epitaxial grow a polysilicon layer from the seed layer 240. The polysilicon layer may have a thickness for fully filling the first contact hole H1. The silicon source may include the monosilane used as the first precursor. Alternatively, the silicon source may include a third precursor such as a silicon source having a multiple silicon coupler, for example, disilane. A doping gas may be supplied simultaneously with the silicon source to provide the polysilicon layer with conductivity. The doping gas may have an impurity type substantially the same as that of the drain D. For example, when the contact pad region 230 on the drain D has an N type impurity, the doping gas may include a PH₃ gas. When the second precursor such as the DCS is supplied during the process for forming the polysilicon layer, the growth of the polysilicon layer may be slowly progressed. Thus, the surface roughness of the polysilicon layer may be improved to reduce voids and seams in the first contact hole H1. Further, the amount ratio between the first precursor and the second precursor may be about 3˜7:1 considered a growth rate of the polysilicon layer.

The semiconductor substrate 200 may be unloaded from the process chamber. The polysilicon layer may be etched-back until the surface of the first insulating interlayer 235 may be exposed to form a bit line contact plug 245 in the first contact hole H1. A conductive layer may be formed on the first insulating interlayer 235. The conductive layer may then be patterned to form a bit line 250 making contact with the bit line contact plug 245.

Referring to FIG. 17, a second insulating interlayer 255 may be formed on the first insulating interlayer 235 with the bit line 250. The second insulating interlayer 255 may include silicon oxide. Further, the second insulating interlayer 255 may include a material having a planarization function. The second insulating interlayer 255 may be etched until the contact pad region on the source S may be exposed to form a second contact hole H2. Additionally, in order to ensure a contact margin, the isolation layer 205 adjacent to the contact pad region 230 on the source S may be partially exposed during forming the second contact hole H2. The second contact hole H2 may correspond to a storage node contact hole.

The semiconductor substrate 200 with the second contact hole H2 may be loaded into the process chamber. The process chamber may include a batch type vertical furnace configured to receive a plurality of the semiconductor substrates 200. An HBr gas may be supplied into the process chamber to dry clean the surface of the contact pad region 230 exposed through the second contact hole H2, the surface of the second insulating interlayer 255 and the inner surface of the second contact hole H2. The exposed upper surface of the contact pad region 230 may be partially etched by the dry cleaning process to remove a native oxide layer on the contact pad region 230. Thus, damages to the first and second insulating interlayers 235 and 255 and the isolation layer 205 may be decreased. Additionally, a wet cleaning process or a dry cleaning process may be performed between the process for forming the second contact hole H2 and the process for loading the semiconductor substrate 200 into the process chamber.

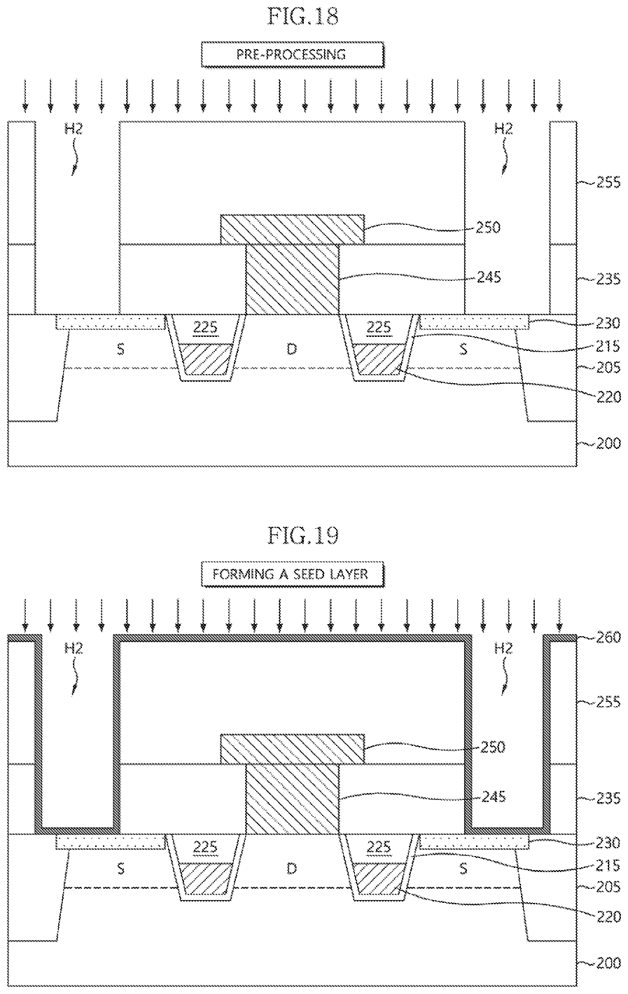

Referring to FIG. 18, a liquid source such as DIPAS may be supplied into the process chamber without cutoff of vacuum to pre-process the exposed contact pad region 230, the surface of the second insulating interlayer 255 and the inner surface of the second contact hole H2. The pre-process may remove dangling bonds on the exposed contact pad region 230, the surface of the second insulating interlayer 255 and the inner surface of the second contact hole H2 to form environments of the surfaces of the exposed contact region 230, the second insulating interlayer 255 and the second contact hole H2 where the seed such may be readily adsorbed.

Referring to FIG. 19, the first precursor and the second precursor may be supplied into the process chamber without the cutoff of the vacuum to form a seed layer 260 on the exposed upper surface of the contact pad region 230, the upper surface of the second insulating interlayer 255 and the inner surface of the second contact hole H2. In examples of embodiments, because the first and second precursors may be supplied simultaneously with each other, the seed layer 260 may have improved density.

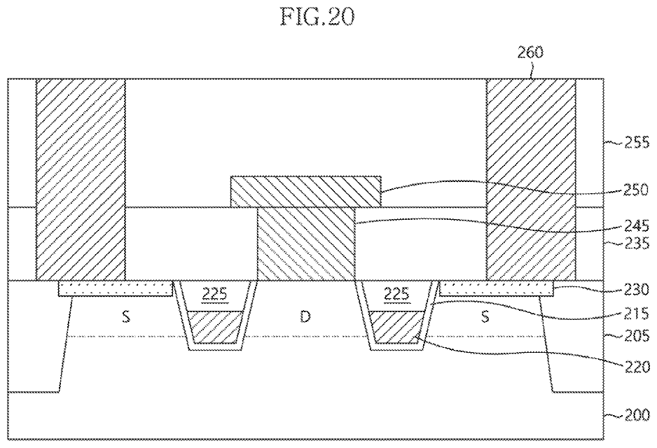

Referring to FIG. 20, a silicon source may be supplied into the process chamber to epitaxial grow a polysilicon layer from the seed layer 260. The silicon source may include the first precursor and/or the third precursor, the second precursor and the doping gas. When the silicon source may include the first precursor or the third precursor, the second precursor may function to improve the surface roughness of the polysilicon layer. The doping gas may function to provide the polysilicon layer with conductivity. Further, the amount of ratio between the first precursor and the second precursor may be about 3˜7:1 to ensure a deposition rate of the polysilicon layer. The first precursor and/or the third precursor, the second precursor and the doping gas may be supplied until the polysilicon layer may have a target thickness. In an embodiment, ‘˜’ indicates a range of values, for example but not limited to, 3 to 7.

The polysilicon layer may then be planarized until the surface of the second insulating interlayer 255 may be exposed to form a storage node contact plug 260. Although not depicted in drawings, a storage node electrode may be formed on the storage node contact plug 260.

According to examples of embodiments, after forming the bit line contact hole or the storage node contact hole having the high aspect ratio, the cleaning process and the polysilicon growth process may be performed in-situ to suppress the generation of the native oxide layer. Particularly, because the cleaning process may use the HBr gas for etching the silicon, the native oxide layer on the junction region or the contact pad region may be selectively removed without the damage of the insulating interlayer.

Further, when the processes for forming the seed layer and the polysilicon layer is performed, the silicon source without CI and the silicon source with CI may be simultaneously supplied so that the density of the seed layer may be improved and the growth of the polysilicon layer may be slowly progressed. Thus, the polysilicon layer may have the improved surface roughness to form the polysilicon plug without the void and the seam.

The above described embodiments are intended to illustrate and not to limit the present disclosure. Various alternatives and equivalents are possible. The embodiments are not limited by the embodiments described herein. Nor are the embodiments limited to any specific type of semiconductor device. Other additions, subtractions, or modifications are obvious in view of the present disclosure and are intended to fall within the scope of the appended claims.

1. A method of forming a contact plug of a semiconductor integrated circuit device, the method comprising:
forming an insulating interlayer on a semiconductor substrate having a conductive region including silicon;
etching the insulating interlayer until the conductive region is exposed to form a contact hole in the insulating interlayer;
loading the semiconductor substrate into a process chamber;
supplying an etching gas into the process chamber to dry clean surfaces of the contact hole and the conductive region;
supplying a silicon source and a source for suppressing a growth of the silicon into the process chamber, at time periods that at least partially overlap each other, to form a seed layer on the surfaces of the contact hole and the conductive region; and
supplying a silicon source into the process chamber to grow a polysilicon layer from the seed layer.

2. The method of claim 1, wherein dry cleaning the surfaces of the contact hole and the conductive region, forming the seed layer and growing the polysilicon are successively performed in the process chamber without a cutoff of vacuum.

3. The method of claim 1, wherein the etching gas comprises a hydrogen bromide (HBr) gas.

4. The method of claim 1, further comprising pre-processing a surface of the insulating interlayer, an inner surface of the contact hole and an exposed surface of the conductive region between dry cleaning the surfaces of the contact hole and the conductive region and forming the seed layer to remove dangling bonds generated on the surface of the insulating interlayer, the inner surface of the contact hole and the exposed surface of the conductive region.

5. The method of claim 4, wherein pre-processing the surface of the insulating interlayer, the inner surface of the contact hole and the exposed surface of the conductive region comprises supplying a diisopropylaminosilane (DIPAS) source into the process chamber.

6. The method of claim 1, wherein the silicon source used for forming the seed layer comprises a silicon precursor without chlorine (Cl).

7. The method of claim 1, wherein the source used for suppressing the growth of the silicon comprises a silicon precursor with Cl.

8. The method of claim 1, wherein forming the seed layer comprises substantially simultaneously supplying the silicon source and the source for suppressing the silicon growth.

9. The method of claim 1, wherein growing the polysilicon layer comprises supplying a doping gas for providing the polysilicon layer with conductivity substantially simultaneously with the silicon source.

10. The method of claim 1, wherein growing the polysilicon layer comprises a doping gas for providing the polysilicon layer with conductivity and a gas for suppressing the silicon growth together with the silicon source.

11. The method of claim 10, wherein the gas for suppressing the silicon growth comprises a silicon source with Cl.

12. The method of claim 10, wherein the silicon source comprises a silicon source without Cl.

13. The method of claim 12, wherein the silicon source for forming the polysilicon layer comprises at least one of monosilane and disilane.

14. The method of claim 1, wherein growing the polysilicon layer comprises providing the polysilicon layer with a thickness for filling the contact hole.

15. The method of claim 14, further comprising planarizing the polysilicon layer until the surface of the insulating interlayer is exposed after growing the polysilicon layer.

16. The method of claim 1, wherein the process chamber comprises a batch type vertical furnace configured to receive a plurality of the semiconductor substrates.

17. The method of claim 16, wherein the process chamber comprises a first gas pipe for the dry cleaning process, a second gas pipe for transferring the silicon source and a third gas pipe for transferring the source for suppressing the silicon growth, each of the first to third pipes comprises at least one pipe, and the first to third pipes have different heights.

18. A method of forming a contact plug of a semiconductor integrated circuit device, the method comprising:
forming an insulating interlayer on a semiconductor substrate having a conductive region including silicon;
etching the insulating interlayer until the conductive region is exposed to form a contact hole in the insulating interlayer;
dry cleaning surfaces of the contact hole and the conductive region; and
using first and second precursors to form a seed layer on the surfaces of the contact hole and the conductive region, the first precursor configured to supply a silicon source and the second precursor configured to suppress a growth of the silicon.

19. The method of claim 18, further comprising forming the contact plug from the seed layer.

20. The method of claim 18, wherein the first and second precursors are used within time periods which substantially simultaneously overlap each other.

21-24. (canceled)
